(19) United States
(12) Patent Application Publication
(10) Pub. No.: US 2026/0113999 A1
(43) Pub. Date: Apr. 23, 2026

(54) THREE DIMENSIONAL BIPOLAR TRANSISTOR

(71) Applicant: Texas Instruments Incorporated, Dallas, TX (US)

(72) Inventors: Josh Lane, Sherman, TX (US); Todd D. Stubblefield, Sherman, TX (US)

(21) Appl. No.: 18/919,548

(22) Filed: Oct. 18, 2024

(51) Int. Cl. H01L 29/08; H01L 29/04; H01L 29/10; H01L 29/66; H01L 29/735

(52) U.S. Cl. CPC H10D 62/134; H10D 10/061; H10D 10/60; H10D 62/184; H10D 62/405

(57) ABSTRACT

A semiconductor device includes a base region having a first conductivity type, the base region extending into a top surface of a semiconductor layer, a collector region having an opposite second conductivity type, the collector region extending from the top surface into the semiconductor layer and spaced apart from the base region, and an emitter region having the second conductivity type, the emitter region extending from the top surface into the base region and having first and second faces along a junction between the emitter region and the base region.

### BACKGROUND

Modern designs call for increased power density and smaller integrated circuit packages. However, bipolar junction transistor (BJT) current carrying capability and device area are typically tradeoffs, with higher current achievable at the expense of larger area. The collector current capability is largely determined by the emitter size and conventional materials and fabrication processes are unable to reduce emitter area to shrink device size while maintaining or increasing current.

### SUMMARY

In one aspect, a semiconductor device includes a base region having a first conductivity type, the base region extending into a top surface of a semiconductor layer, a collector region having an opposite second conductivity type, the collector region extending from the top surface into the semiconductor layer and spaced apart from the base region, and an emitter region having the second conductivity type, the emitter region extending from the top surface into the base region and having first and second faces along a junction between the emitter region and the base region.

In another aspect, a semiconductor device includes a base region having a first conductivity type, the base region extending into a top surface of a semiconductor layer, the top surface of the semiconductor layer extending in a plane of orthogonal first and second directions, a collector region having an opposite second conductivity type, the collector region extending from the top surface into the semiconductor layer and spaced apart from the base region, and an emitter region having multiple emitter fingers of the second conductivity type, the emitter fingers spaced apart from one another along the first direction and extending longitudinally along the second direction and into the semiconductor layer at an angle to the top surface of the semiconductor layer, each emitter finger having first and second faces with respective first and second current emitting surfaces along a junction between the emitter region and the base region.

In a further aspect, a method includes forming a collector region in a semiconductor layer, forming an angled structure in the semiconductor layer, forming a base region in the angled structure of the semiconductor layer, the base region extending into a surface of the angled structure and spaced apart from the collector region, wherein the base region has a first conductivity type and the collector region has a second conductivity type opposite to the first conductivity type, and forming an emitter region extending from the surface of the angled structure into the base region and having first and second faces along a junction between the emitter region and the base region, wherein the emitter region has the second conductivity type.

### BRIEF DESCRIPTION OF THE DRAWINGS

FIG. 1 is a partial sectional side elevation view of a semiconductor device taken along line 1-1 of FIG. 1A.

FIG. 1A is a partial sectional top view of the semiconductor device taken along line 1A-1A of FIG. 1.

FIG. 1B is a top perspective view of the semiconductor device of FIGS. 1 and 1A.

FIG. 2 is a flow diagram of a method of fabricating a semiconductor device.

FIGS. 3-12 are partial side elevation views of the semiconductor device of FIGS. 1-1B undergoing fabrication processing according to the method of FIG. 2.

FIG. 13 is a partial sectional side elevation view of another semiconductor device.

FIG. 14 is a partial sectional side elevation view of yet another semiconductor device.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating. Described examples include doped regions of various semiconductor structures which may be characterized as p-doped and/or n-doped regions or portions and include regions that have majority carrier dopants of a particular type, such as n-type dopants or p-type dopants, and such regions or portions should be interpreted as having the conductivity type as n-type or p-type, respectively. Certain example NPN bipolar junction transistors (BJTs) are illustrated and described as having doped regions of the first and second conductivity types, where the first conductivity type is p-type in the second conductivity type is n-type. Other examples are possible with reversal of the conductivity types, for example, to form PNP bipolar transistors where the first conductivity type is n-type in the second conductivity type is p-type.

One or more structures, features, aspects, components, etc., may be referred to herein as first, second, third, etc., such as first and second terminals, first, second, and third, wells, etc., for ease of description in connection with a particular drawing, where such are not to be construed as limiting with respect to the claims. Various disclosed structures and methods of the present disclosure may be beneficially applied to manufacturing a semiconductor device such as an integrated circuit or a BJT. While such examples may be expected to provide various improvements, no particular result is a requirement of the present disclosure unless explicitly recited in a particular claim.

Described examples facilitate high transistor current performance along with small device area using three dimensional (3D) structures to mitigate the trade-off between device area and current carrying capability of conventional designs. For example, angled features, fins, etc. can be used to facilitate increased transistor current for a given transistor size and/or reduced device size without sacrificing current performance. Certain examples create angled features using etch processing to create triangular or prism shaped trenches, for example, in (100) crystal oriented silicon wafers. The triangular or prism shaped trenches having multiple faces in one example are implanted after etching so as to form respective emitter and base regions of a BJT with bulk silicon (e.g., epitaxial silicon) serving as a collector of the BJT. In this manner, current emitting surfaces can be increased for improved performance of the BJT compared with a single planar emitter face.

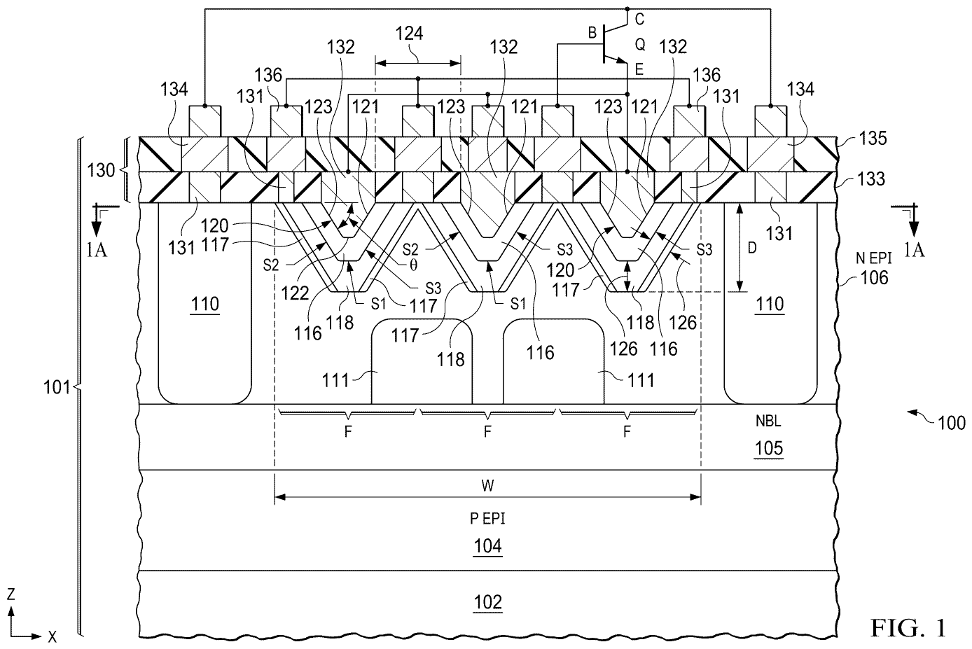

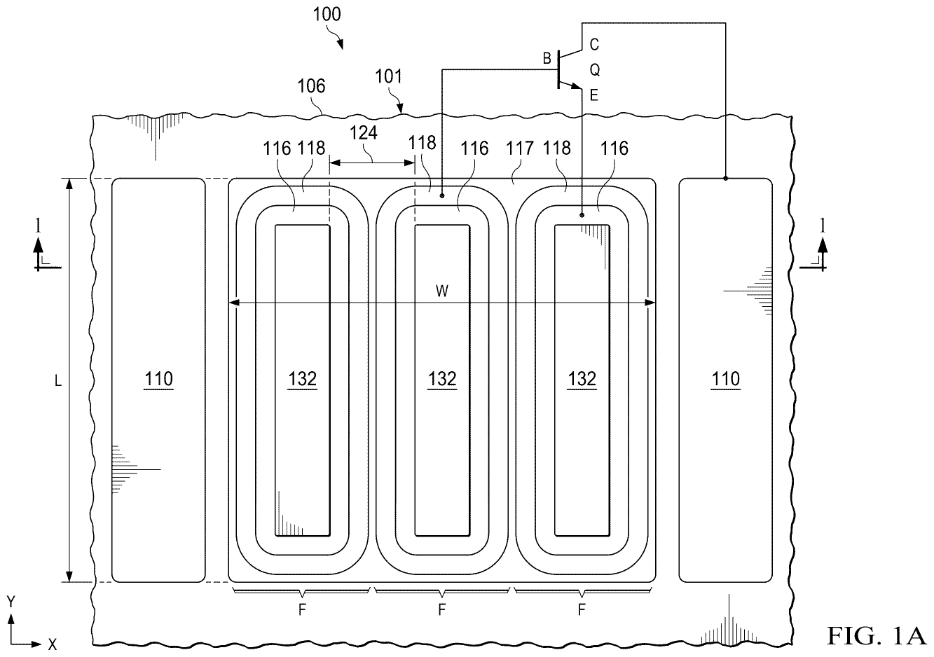

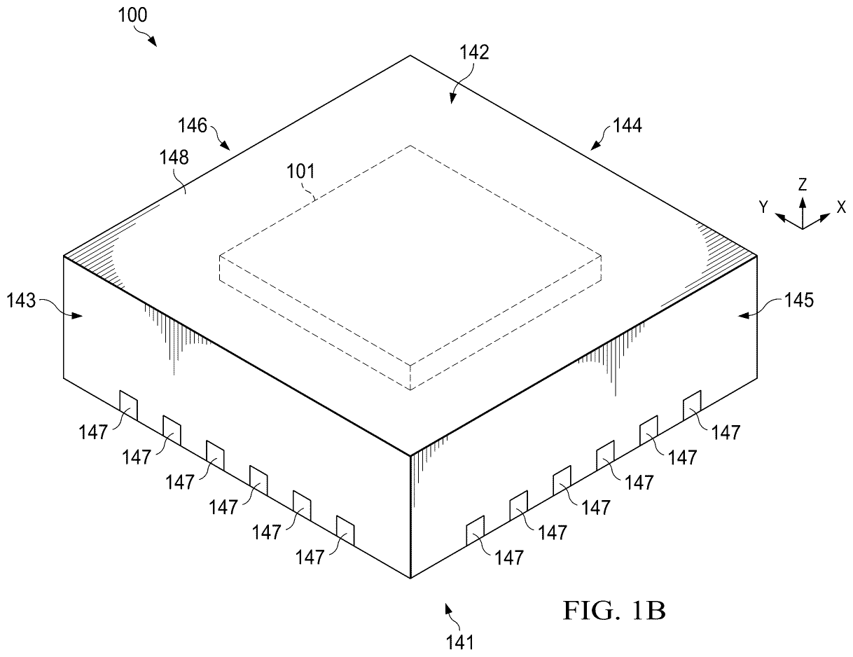

FIGS. 1, 1A and 1B show an example semiconductor device 100 with a semiconductor die 101 that includes a semiconductor substrate 102 (FIG. 1) that is or includes silicon or other suitable semiconductor material. FIG. 1 shows a partial sectional side view of a portion of the semiconductor device 100 taken along line 1-1 of FIG. 1A, FIG. 1A shows a partial sectional top view taken along line 1A-1A of FIG. 1, and FIG. 1B shows a perspective view of the semiconductor device 100. The example semiconductor device 100 is shown in FIGS. 1 and 1A in an example three-dimensional space with a first direction X, a perpendicular (orthogonal) second direction Y (FIG. 1A), and a third direction Z (FIG. 1) that is perpendicular (orthogonal) to the respective first and second directions X and Y.

The semiconductor substrate 102 may have a first conductivity type (e.g., includes majority carrier dopants of a first type, such as p-type, labeled “SUBSTRATE” in FIG. 1). The semiconductor device 100 includes an example NPN bipolar junction transistor schematically designated “Q” in FIG. 1 with a base B, a collector C, and an emitter E. The semiconductor device 100 is shown to include a semiconductor layer 104 (e.g., epitaxial silicon, which may be referred to as second semiconductor layer 104 or epitaxial layer 104) that extends above the semiconductor substrate 102 as shown in FIG. 1. The semiconductor layer 104 has the first conductivity type (e.g., includes majority carrier dopants of the first type, such as p-type, labeled “P EPI” in FIG. 1). In some examples, the semiconductor layer 104 may be omitted.

The semiconductor device 100 includes a buried layer 105 having an opposite second conductivity type (e.g., includes majority carrier dopants of a second type, such as n-type, labeled “NBL” in FIG. 1). The buried layer 105 may extend from the semiconductor substrate 102 or from the epitaxial semiconductor layer 104 (if present). In the examples described hereinafter, the first conductivity type is p-type and the second conductivity type is n-type. In other implementations not explicitly shown, similar benefits and structures can be fabricated by reversing the conductivity types of various structures, for example, wherein the first conductivity type can be n-type and the second conductivity type can be p-type.

As shown in FIG. 1, a semiconductor layer 106 (e.g., epitaxial silicon, which may be referred to as a semiconductor layer 106 or epitaxial layer 106) extends over the semiconductor substrate 102 and from the buried layer 105. The semiconductor layer 106 has the second conductivity type (e.g., includes n-type majority carriers) and is labeled “N EPI” in FIG. 1. The semiconductor layer 106 has a top surface that extends in a plane of the respective first and second directions X and Y. In one example, the semiconductor layer 106 is or includes silicon, and the top surface of the semiconductor layer 106 has a crystal orientation of Miller indices (100). In other examples, the semiconductor layer 106 may have a crystal orientation different than Miller indices (100). An upper portion of the buried layer 105 extends into a lower portion of the semiconductor layer 106 in the illustrated example, for example, by diffusion of n-type dopants originally implanted in the semiconductor substrate 102 or in the epitaxial layer 104 (if present) into the lower portion of the semiconductor layer 106.

In the illustrated example, the transistor Q is an NPN transistor and includes a collector C implemented as an n-type collector region 110. The collector region 110 extends downward along the third direction Z from the top surface of the semiconductor layer 106 to the buried layer 105. The illustrated example also has collector fins 111 that extend along the second direction Y (e.g., into the page in FIG. 1) and are located laterally between emitter fingers F. The illustrated example has three emitter fingers F. In other examples, more or fewer fingers F can be provided. The collector region 110 has majority carriers of the second type with a dopant concentration that is greater than that of the n-type epitaxial layer 106.

The semiconductor device 100 has emitter regions 116 with the second conductivity type (N). The emitter regions 116 extend from the top surface of the semiconductor layer 106 into a base region 118 and have multiple faces with respective current emitting surfaces S1-S3 along respective junctions between the emitter regions 116 and the base region 118. The emitter region 116 has multiple emitter fingers F of the second conductivity type. The emitter fingers F are spaced apart from one another along the first direction X. As shown in FIG. 1A, the emitter fingers F extend longitudinally along the second direction Y. The angled first and second faces of each emitter finger F of the respective emitter regions 116 are not parallel to one another and are not parallel to the plane of the top surface of the semiconductor layer 106. The angled first and second faces of the individual emitter regions 116 are at respective nonzero first and second angles θ to the plane of the top surface of the semiconductor layer 106. The angle θ to the top surface of the semiconductor layer 106 in one example is greater than 0 degrees and less than 90 degrees.

The multi-finger emitter structure of the transistor Q has a width W along the first direction X (FIGS. 1 and 1A), and a length L (FIG. 1A). As shown in FIG. 1, the emitter regions 116 of each finger F extend into the semiconductor layer 106 at a non-zero acute angle θ to the top surface of the semiconductor layer 106. Each emitter finger F has first and second angled faces with respective first and second current emitting surfaces S1 and S3 along a junction between the emitter region 116 and the corresponding base region 118. The emitter regions 116 are each formed in a corresponding trench 120 with angled sidewalls 121, 123 and trench bottoms 122. In some examples, the trench bottoms 122 may be generally flat—e.g., approximately parallel to the top surface of the semiconductor layer 106. In other examples, the trench bottoms 122 may not be generally flat—e.g., not parallel to the top surface of the semiconductor layer 106.

The transistor base B is formed by one or more base regions 118 corresponding to the emitter fingers F and the base regions 118 have the first conductivity type P. The base regions 118 extend into the top surface of a semiconductor layer 106. The illustrated semiconductor device 100 in FIGS. 1 and 1A also includes base sidewall guard regions 117 along portions of the respective base regions 118 and having the first conductivity type P. The base sidewall guard regions 117 are spaced apart from the corresponding emitter regions 116. In some examples, the p-type dopant concentrations of the base sidewall guard regions 117 is greater than the p-type dopant concentration of the base regions 118. In other implementations, the base sidewall guard regions 117 can be omitted.

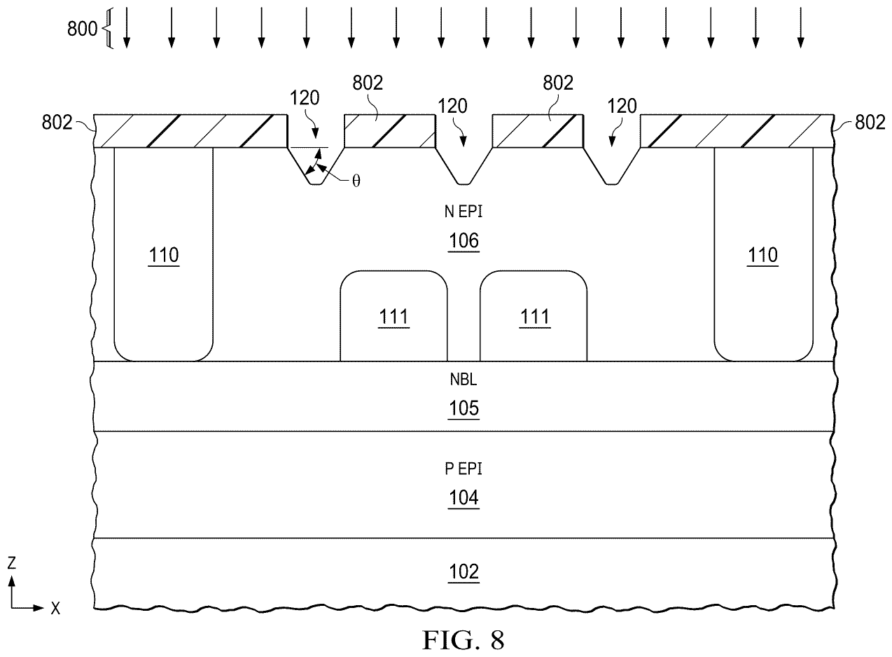

As further shown in FIGS. 1 and 1A, the trenches 120 are laterally spaced apart from one another along the first direction X by a non-zero spacing distance 124 (FIG. 1), such that the emitter fingers F are spaced apart from one another along the first direction X. The trench spacing 124 can help facilitate formation of an etch mask used to etch the trenches 120 during fabrication processing (e.g., FIG. 8 below). The angled structure of the respective emitter and base regions 116 and 118 (and any included base sidewall guard regions 117) provides an approximately uniform base dimension 126 between the current-emitting surfaces S1-S3 of the emitter region 116 and the outer edges of the base B.

The semiconductor device 100 includes a metallization structure 130 as shown in FIG. 1. The metallization structure 130 includes first and second vertical metal interconnects 131 and 132 (e.g., vias or contacts including tungsten or other suitable conductive metal) in a pre-metal dielectric (PMD) layer 133, and a metal trace features 134 in a first interlevel or interlayer dielectric (ILD) layer 135. The metal interconnects 132 for the transistor emitter extend into the trenches 120 along the sidewalls 121, 123 and the trench bottoms 122 to form metal layer contacts to the sidewalls 121, 123 and the bottom 122 of the trenches 120. The metal interconnects 132 can, but need not, completely fill the corresponding trenches 120. The metal trace features 134 and other metal trace features may include aluminum or copper traces formed by any suitable process. The metallization structure 130 in one example includes a third level with conductive metal terminals 136, such as bond pads, die pads, etc., that can provide terminal connections to interconnect the semiconductor die 101 and the transistor Q thereof, for example, by bond wire connections, or soldering of one or more terminals 136 to a substrate or lead frame (not shown) during packaging of the semiconductor device 100. The contacts (e.g., interconnects 131 and 132) of the PMD level extend downward along the third direction Z to provide electrical connection to respective portions of the top side of the epitaxial semiconductor layer 106 and into the emitter finger trenches 120, and the connections may include conductive metal silicide and/or more heavily doped contacts within the semiconductor layer 106 (not shown).

As further shown in FIG. 1B, the semiconductor device 100 in one example is an integrated circuit or a component having the above-described semiconductor die 101 packaged with electrical connections formed between conductive terminals (e.g., terminals 136) and one or more conductive features of a starting lead frame and/or a package substrate (not shown). The package interconnections can be made by any suitable structures and techniques, including without limitation wire bonding, flip chip soldering of the terminals 136 of the semiconductor die 101, etc. The example semiconductor device 100 in FIG. 1B has opposite bottom and top sides 141 and 142 spaced apart from one another along the third direction Z, respectively, as well as laterally opposite third and fourth sides 143 and 144, and laterally opposite ends 145 and 146. The semiconductor die 101 has one or more terminals electrically connected to respective ones of conductive metal leads 147, for example, conductive portions of a starting lead frame and/or package substrate (not shown). In this example portions of the leads 147 and the semiconductor die 101 are at least partially enclosed by a molded or ceramic package structure 148 that defines the sides 141-146. The leads 147 can be soldered or otherwise electrically connected to a host system (e.g., a printed circuit board or PCB, not shown) by suitable solder connections, installation in a socket, etc.

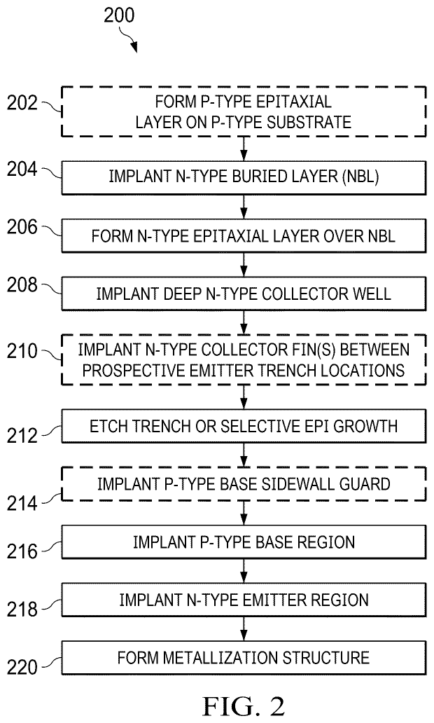

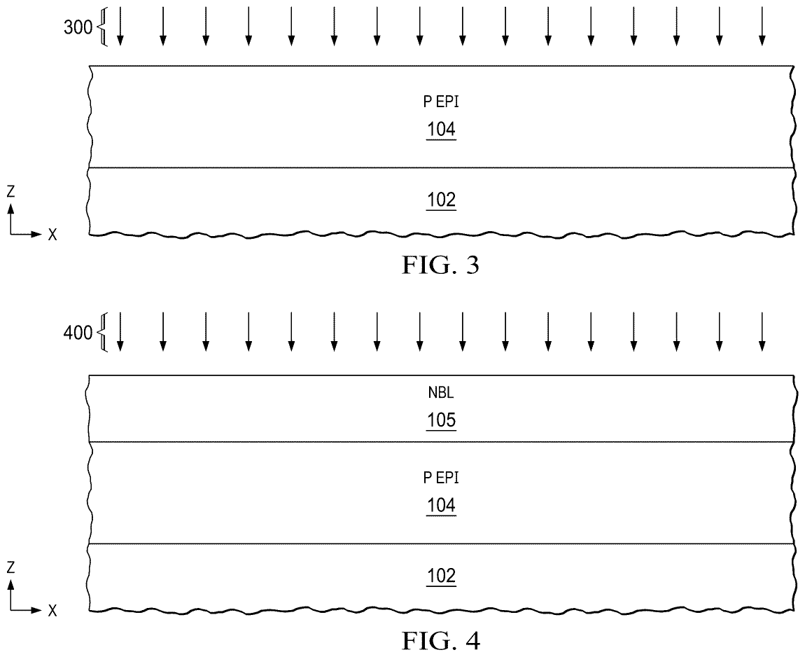

Referring also to FIGS. 2-12, FIG. 2 shows a method 200 of fabricating a semiconductor device and FIGS. 3-12 show the example semiconductor device 100 undergoing fabrication processing according to the method 200. The method 200 may begin at step 202 in FIG. 2 with optionally forming an epitaxial layer on a substrate. FIG. 3 shows one example, in which an epitaxial deposition (e.g., growth) process 300 is performed that grows epitaxial layer 104 on a top side of a starting substrate 102 (e.g., during processing of multiple unit or die areas of a starting wafer that includes the substrate 102). The epitaxial deposition process 300 in one example includes provision of process gas that includes p-type dopants (e.g., boron, etc.) to provide a p-type epitaxial layer 104 on the substrate 102. In other examples, forming the p-type epitaxial layer may be omitted.

The method 200 continues at step 204 in FIG. 2 with an implantation process 400 forming the buried layer 105. FIG. 4 shows one example, in which the implantation process 400 is performed, which may use an implant mask (not shown). The implantation process 400 implants n-type dopants (e.g., phosphorus, etc.) into the exposed portions of the top side of the p-type epitaxial semiconductor layer 104 (or into the exposed portions of the top side of the semiconductor substrate 102 if the p-type epitaxial semiconductor layer 104 is omitted) to provide a net n-type doping of the buried layer 105, where the buried layer 105 includes majority carriers of the second type (e.g., n-type).

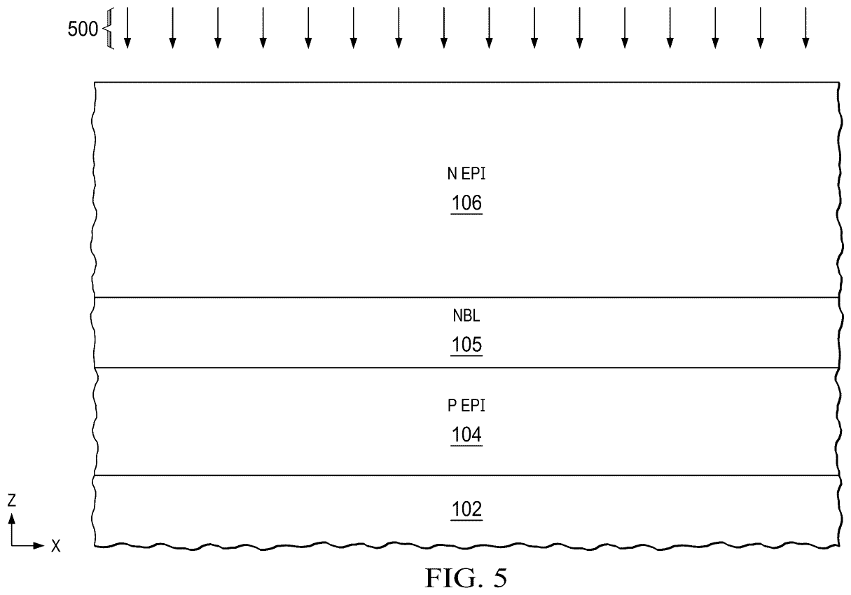

The method 200 continues at step 206 in FIG. 2 with forming the n-type epitaxial semiconductor layer 106 over the buried layer 105. FIG. 5 shows one example, in which an epitaxial deposition (e.g., growth) process 500 is performed that deposits (e.g., grows) n-type doped epitaxial silicon to form the epitaxial semiconductor layer 106 over the n-type buried layer 105. The epitaxial deposition process 500 in one example includes provision of process gas that includes n-type dopants (e.g., phosphorus, etc.) to provide the n-type doped epitaxial silicon layer 106. The deposition process 500 in one example may cause a slight upward diffusion of previously implanted n-type dopants (e.g., phosphorus) from the buried layer 105, and the dopant diffusion extends the buried layer 105 into a lower portion of the deposited n-type epitaxial semiconductor layer 106 as shown in FIG. 5.

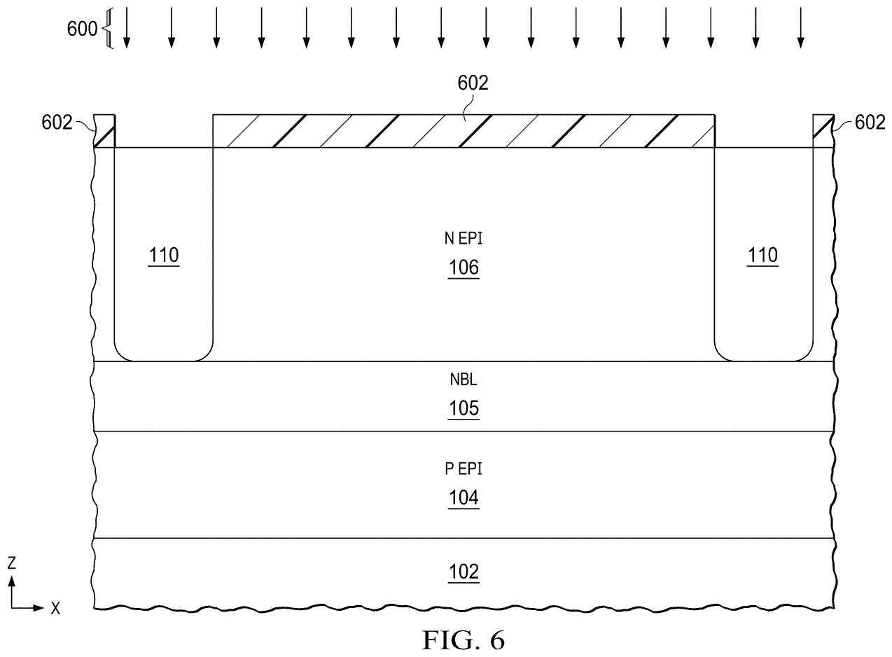

The method 200 continues at step 208 in FIG. 2 with implantation of deep n-wells to form the collector regions 110 in the semiconductor layer 106 and extending to the buried layer 105. FIG. 6 shows one example, in which an implantation process 600 is performed with an implant mask 602 that exposes prospective first and second collector portions of the top surface of the n-type epitaxial semiconductor layer 106 in each unit area or prospective die area of the processed wafer. The implantation process 600 implants n-type dopants to form the deep implanted collector regions 110 as shown in FIG. 6. The implanted regions 110 include n-type dopants (e.g., phosphorus) with a dopant concentration in one example that is higher than that of the n-type epitaxial semiconductor layer 106. In one example, the collector region implants at step 208 can include post implant annealing, for example, to diffuse the collector implants all the way down to the buried layer 105.

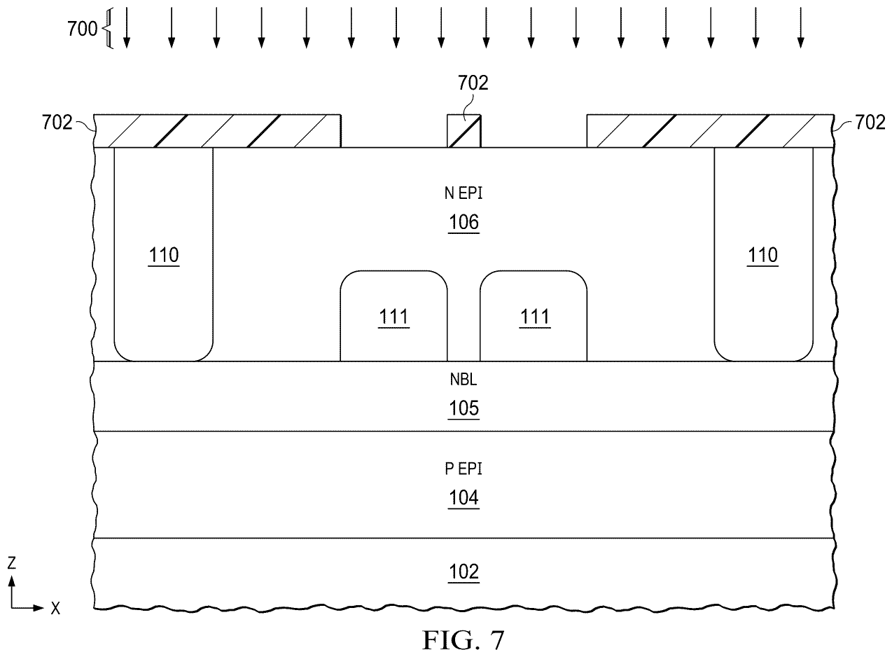

The method 200 continues in one example at step 210 in FIG. 2 with optional implantation of the collector fins 111. FIG. 7 shows one example, in which an implantation process 700 is performed with an implant mask 702 that exposes prospective first and second collector fins 111 between prospective emitter finger regions of the top surface of the n-type epitaxial semiconductor layer 106 in each unit area or prospective die area of the processed wafer. The implantation process 700 implants n-type dopants to form the deep implanted collector fins 111 that extend to the buried layer 105. In one example, the implanted collector fins 111 include n-type dopants (e.g., phosphorus) with a majority carrier dopant concentration in that is higher than that of the n-type epitaxial semiconductor layer 106. In one example, the optional collector fin implantation at 210 can include post implant annealing, for example, to diffuse the dopants of the implanted collector fins 111 down to the buried layer 105. In other implementations, the collector fins 111 and the implantation processing at 210 can be omitted.

The example method 200 further includes processing at step 212 to form the angled structures in or on the n-type epitaxial semiconductor layer 106—e.g., emitter structures along one or more fingers (e.g., emitter fingers F in FIGS. 1 and 1A above). In one example, the processing includes trench etching at step 212 to form angled surfaces such as sidewalls of an etched trench for further implantation to form angled emitter finger structures in the semiconductor layer 106. In another example, selective epitaxial growth process can be performed at step 212 in order to form angled structures followed by subsequent implantation steps to form angled emitter structures at an angle to the plane of the top surface of the semiconductor layer 106.

FIG. 8 shows one example, in which an etch process 800 is performed using a patterned etch mask 802 that etches one or more trenches 120 into the top surface of the semiconductor layer 106, where the etched trenches 120 are laterally spaced apart (e.g., along the first direction X) from the collector regions 110. The etch process 800 in one example is an anisotropic etch that forms the trench 120 having laterally opposite sidewalls (e.g., 121 and 123 in FIG. 1 above) that extend from the top surface of the semiconductor layer 106 to a trench bottom (e.g., trench bottom 122 in FIG. 1) at an angle θ to the top surface of the semiconductor layer 106, where the angle θ is greater than 0 degrees and less than 90 degrees. Any suitable anisotropic etch process 800 can be used, including wet etching, dry etching, etc. In one example, the semiconductor layer 106 is or includes silicon, the top surface of the semiconductor layer 106 having a crystal orientation of Miller indices (100), and the etch process 800 is a crystallographic wet etch process. In one example, the etch mask 802 is or includes a nitride to form an etch mask with openings corresponding to the prospective trenches 120. In one example, the etch process 800 is a KOH wet etch to form the angled sidewalls 121 and 123 of the etched trenches 120. The dimensions of the etch mask 802 (e.g., the spacing and prospective trench widths) in conjunction with the etch process 800 may be designed to provide trench bottoms 122 of the etched trenches 120 to be substantially planar or flat—e.g., approximately parallel to the top surface of the semiconductor layer 106. In some examples, the trench bottoms 122 of the etched trenches 120 may not be substantially planar or flat. In one example, a post etch nitride strip process is performed to remove the nitride etch mask 802. In one example, the etch process 800 creates the angled sidewall structure of the trenches 120 with an angle θ greater than 0°and less than 90°, such as approximately 40-60°, approximately 55° in one example.

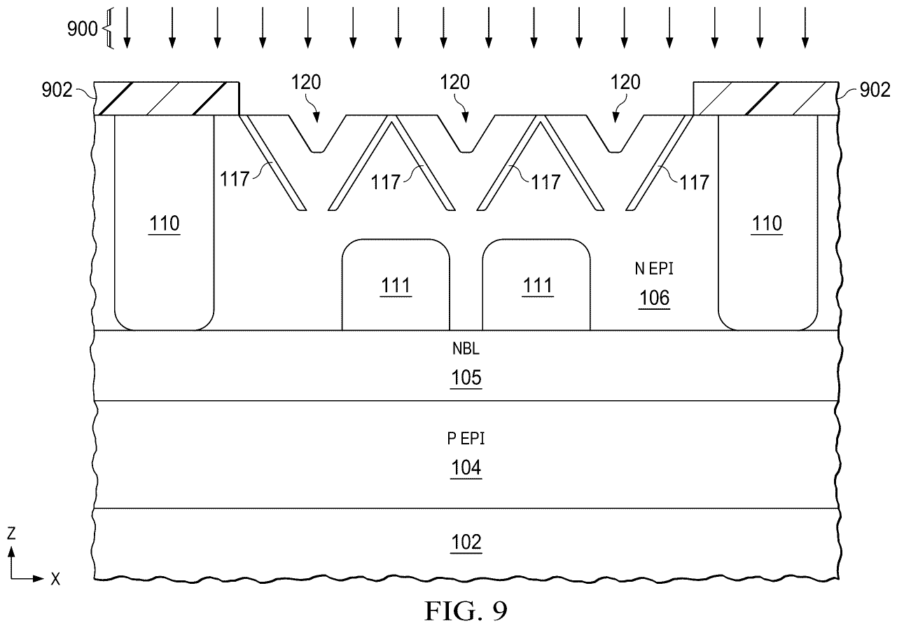

The method 200 in FIG. 2 in one example continues at step 214 with formation of the implanted base B of the BJT. In one implementation, an optional implantation is performed at step 214 to implant the p-type base sidewall guard regions 117 along the prospective finger structures. FIG. 9 shows one example, in which an implantation process 900 is performed with an implant mask 902 in order to implant p-type dopants (e.g., boron) to form the base sidewall guard regions 117. In one example, the implant mask 902 includes a single opening as shown in FIG. 9 that exposes the three prospective finger structures. In another example, the implant mask 902 may include portions (not shown) that inhibit implantation through the bottoms of the trenches, for example, with mask material covering the bottom portions of the etched trenches 120. In one example, the optional base sidewall guard region implantation at step 214 can include post implant annealing, for example, to diffuse the implanted base sidewall guard regions 117 downward in the semiconductor layer 106. In some examples, the implanted base sidewall guard regions 117 may be conjoined at the bottom portions of the etched trenches 120. In another example, the optional implantation at step 214 and the base sidewall guard regions 117 can be omitted.

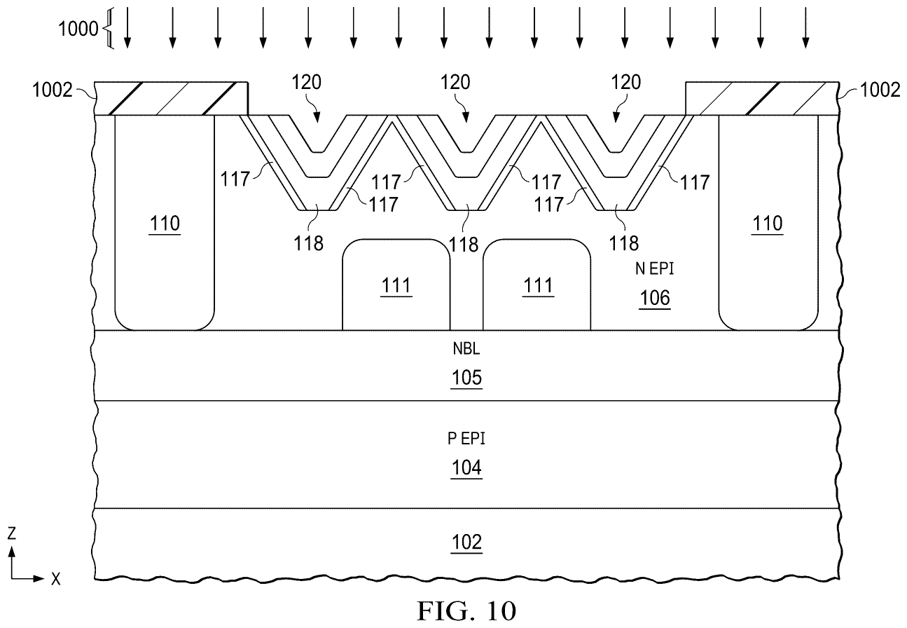

The method 200 continues at step 216 in FIG. 2 with forming the base region 118 in the angled structure provided by the trenches 120. FIG. 10 shows one example, in which an implantation process 1000 is performed using an implant mask 1002 that forms the base region 118 in (e.g., beneath) the angled structure with majority carrier p-type dopants (e.g., boron). The angled structure of the trenches 120 facilitates implantation of approximately V-shaped implanted regions 118 with p-type dopants. In some examples, the implanted regions 118 have a majority carrier p-type dopant density that is less than majority carrier dopant density of any included base sidewall guard regions 117. In one example, the base region implantation at step 216 can include post implant annealing, for example, to diffuse the implanted base region or regions 118 downward in the semiconductor layer 106. In one example, the implant mask 1002 includes a single opening as shown in FIG. 9 that exposes the three prospective finger structures. In another example, a shadow mask process (not shown) can be used to facilitate implantation of the approximately V-shaped implanted base regions 118 in the semiconductor layer 106.

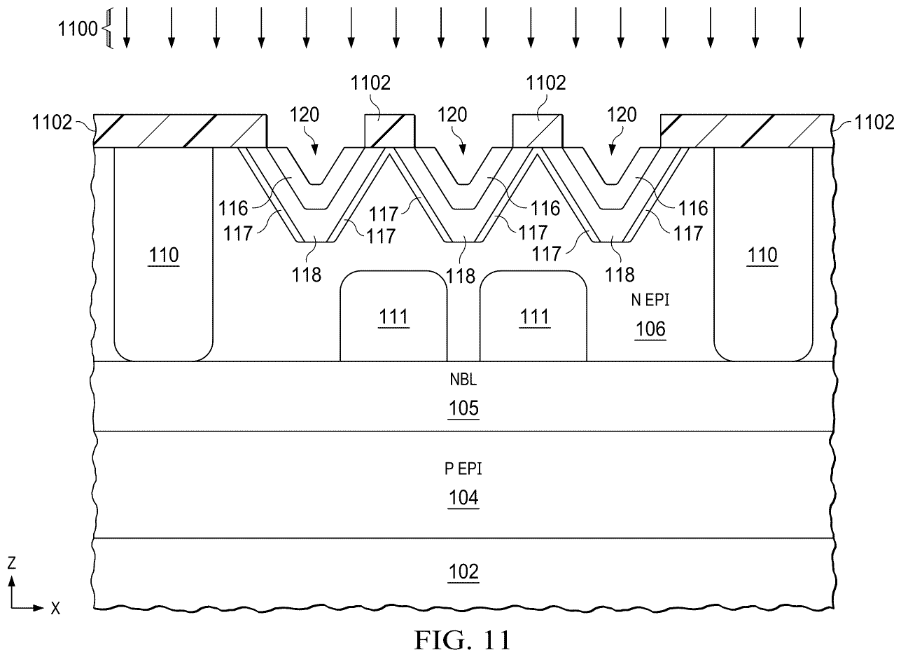

The method 200 in FIG. 2 continues at step 218 with implanting the n-type emitter regions 116. FIG. 11 shows one example, in which an implantation process 1100 is performed with an implant mask 1102 with openings corresponding to the approximately V-shaped emitter regions 116. In one example, the implant mask 1102 includes separate openings for the prospective emitter finger structures as shown in FIG. 11. The implantation process 1100 in one example implants phosphorus or other suitable n-type dopants to form the emitter regions 116 with n-type majority carriers that extend from the sidewalls and bottom of the corresponding trenches 120 and extend to the implanted base regions 118. In one example, the emitter region implantation at step 218 can include post implant annealing, for example, to diffuse the implanted emitter regions 116 downward in the semiconductor layer 106. The implanted emitter regions 116 extend from the surface of the angled trench structures 120 into the base region 118 and each of the emitter regions 116 have angled first and second faces along a junction between the emitter region 116 and the corresponding portion of the base region 118.

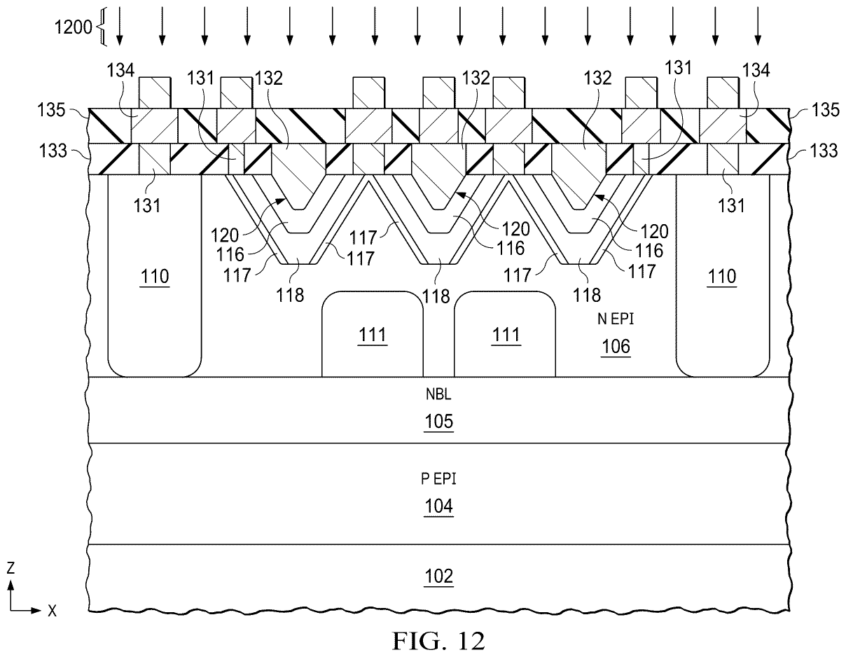

The method 200 continues at step 220 in FIG. 2 with metallization processing to form a single or multilevel metallization structure that includes a metal contact or metal layer (e.g., 132 in FIG. 1 above) that contacts the sidewalls 121, 123 and potentially the bottom 122 of the trenches 120 to form emitter contacts. As previously discussed in connection with FIG. 1A, the illustrated example includes a multilevel metallization structure 130. FIG. 12 shows one example, in which a multistep metallization process 1200 is performed that forms the PMD layer 133 and corresponding tungsten contacts 131 and 132, and then forms the ILD layer and associated conductive metal features (e.g., traces) 134 and any final top level device terminal conductive features. In the illustrated example, the metallization structure provides an electrical connection between the terminals of the bipolar junction transistor Q discussed above in connection with FIGS. 1-1B.

The method 200 in one implementation continues with die separation and packaging operations to separate the individual processed semiconductor dies 101 from the processed substrate 102 by a die separation process (not shown). The method 200 can include further processing associated with packaging, etc. (not shown).

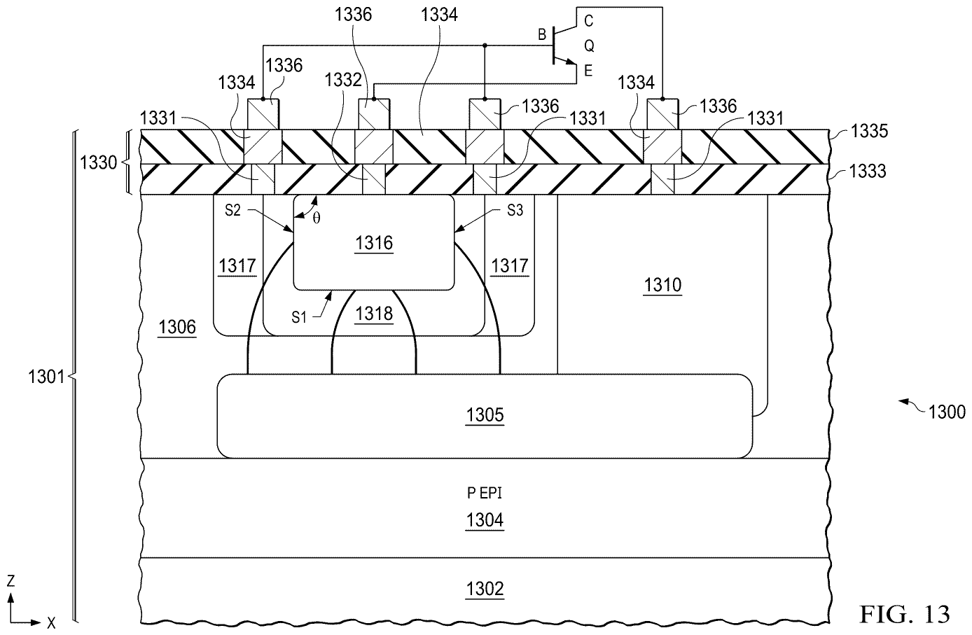

FIG. 13 shows a partial sectional side view of another semiconductor device 1300 with an NPN bipolar transistor Q having a base B, and emitter E, and a collector C. The semiconductor device 1300 includes a semiconductor die 1301 with a semiconductor substrate 1302 that is or includes silicon or other suitable semiconductor material. The substrate 1302 has a first conductivity type (e.g., includes majority carrier dopants of a first type, such as p-type, labeled “SUBSTRATE” in FIG. 13). In some examples, the semiconductor device 1300 also includes a semiconductor layer 1304 (e.g., epitaxial silicon, which may be referred to as second semiconductor layer 1304 or epitaxial layer 1304) that extends above the semiconductor substrate 1302 and has the first conductivity type (e.g., includes majority carrier dopants of the first type, such as p-type, labeled “P EPI” in FIG. 13). In other examples, the semiconductor layer 1304 may be omitted. The semiconductor device 1300 further includes a buried layer 1305 having an opposite second conductivity type (e.g., includes majority carrier dopants of a second type, such as n-type). In the illustrated example, the first conductivity type is p-type and the second conductivity type is n-type. In other implementations not explicitly shown, similar benefits and structures can be fabricated by reversing the conductivity types of various structures, for example, wherein the first conductivity type can be n-type and the second conductivity type can be p-type.

A semiconductor layer 1306 (e.g., epitaxial silicon, which may be referred to as a semiconductor layer 1306 or epitaxial layer 1306) extends over the substrate 1302 from the epitaxial layer 1304 (or from the semiconductor substrate 1302 if the epitaxial layer 1304 is omitted) and from the buried layer 1305. The semiconductor layer 1306 has the second conductivity type (e.g., includes n-type majority carriers) and includes a top surface that extends in a plane of the respective first and second directions X and Y. In one example, the semiconductor layer 1306 is or includes silicon, and the top surface of the semiconductor layer 1306 has a crystal orientation of Miller indices (100). In other examples, the semiconductor layer 1306 may have a crystal orientation different than Miller indices (100). An upper portion of the buried layer 1305 extends into a lower portion of the semiconductor layer 1306 in the illustrated example, for example, by diffusion of n-type dopants originally implanted in the epitaxial layer 1304 (or in the semiconductor substrate 1302 if the epitaxial layer 1304 is omitted) into the lower portion of the semiconductor layer 1306.

In the illustrated example, the transistor Q is an NPN transistor and includes a collector C implemented as an n-type collector region 1310 with a corresponding collector contact 1331 in the PMD layer 1333. The collector region 1310 extends downward along the third direction Z from the top surface of the semiconductor layer 1306 to the buried layer 1305 to form a collector of the transistor Q. The collector region 1310 has majority carriers of the second type with a dopant concentration that is greater than that of the n-type epitaxial layer 1306.

The semiconductor device 1300 includes an emitter region 1316 with the second conductivity type (n-type) that has a vertical fin shape. In some examples, the vertical fin shape of the emitter region 1316 may have an aspect ratio greater than 1, which extends from the top surface of the semiconductor layer 1306 into a base region 1318. As such, the emitter region 1316 with a vertical fin shape may have multiple faces with respective current emitting surfaces S1-S3 along respective junctions between the emitter region 1316 and the base region 1318. The emitter region 1316 is laterally spaced apart from the collector region 1310 and can extend along an orthogonal direction into the page in the view of FIG. 13 to form a single finger structure with current emitting faces along substantially vertical sidewalls S2 and S3 at an angle θ of approximately 90° to the plane of the top surface of the semiconductor layer 1306, as well as a current emitting face along a bottom side S1 of the emitter region 1316. FIG. 13 schematically shows thick lines to depict current flow from the sidewalls S1, S2, and S3 of the emitter region 1316 through respective junctions between the emitter region 1316 and the base region 1318.

The base B of the transmitter Q in this example is formed by a base region 1318 with the first conductivity type (p-type), and the base B may include base sidewall guard regions 1317 along lateral sides of the base region 1318 and spaced apart from the emitter region 1316. In one example, the p-type dopant concentrations of the base sidewall guard regions 1317 is greater than the p-type dopant concentration of the base region 1318. In other implementations, the base sidewall guard regions 1317 can be omitted. The semiconductor device 1300 also includes a metallization structure 1330 with vertical metal interconnects 1331 and 1332 (e.g., vias or contacts including tungsten or other suitable conductive metal) in a pre-metal dielectric (PMD) layer 1333, and a metal trace features 1334 in a first interlevel or interlayer dielectric (ILD) layer 1335. The metallization structure 1330 in one example includes a third level with conductive metal terminals 1336, such as bond pads, die pads, etc., that can provide terminal connections to interconnect the semiconductor die 1301 and the transistor Q thereof, for example, by bond wire connections, or soldering of one or more terminals 1336 to a substrate or lead frame (not shown) during packaging of the semiconductor device 1300.

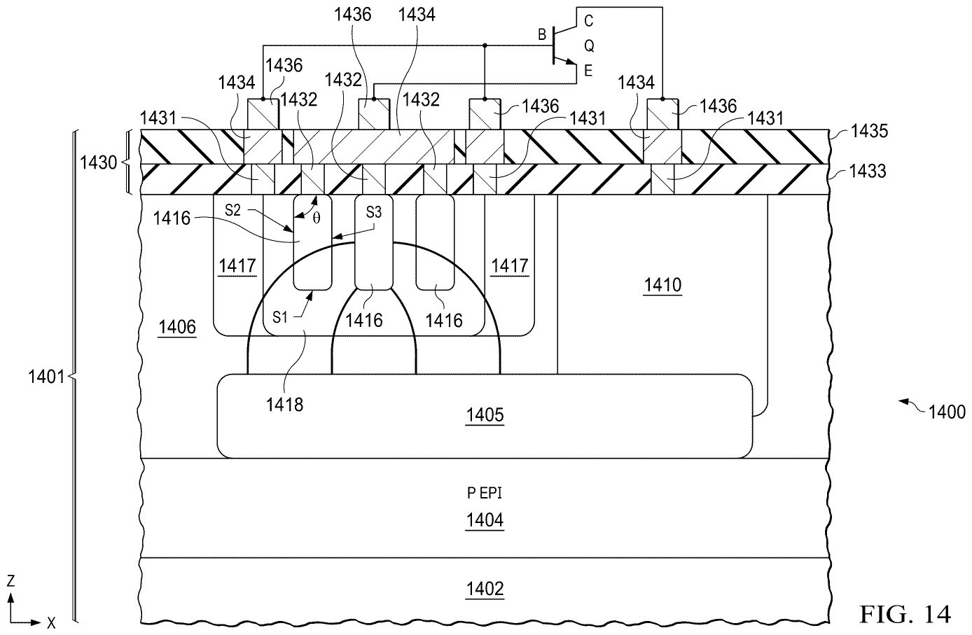

FIG. 14 is a partial sectional side view of yet another semiconductor device 1400 having three dimensional emitter finger or fin structures extending into a semiconductor layer. The semiconductor device 1400 includes an NPN bipolar transistor Q having a base B, and emitter E, and a collector C. The semiconductor device 1400 includes a semiconductor die 1401 with a semiconductor substrate 1402 that is or includes silicon or other suitable semiconductor material. The substrate 1402 has a first conductivity type (e.g., includes majority carrier dopants of a first type, such as p-type, labeled “SUBSTRATE” in FIG. 14). In some examples, the semiconductor device 1400 also includes a semiconductor layer 1404 (e.g., epitaxial silicon, which may be referred to as second semiconductor layer 1404 or epitaxial layer 1404) that extends above the semiconductor substrate 1402 and has the first conductivity type (e.g., includes majority carrier dopants of the first type, such as p-type, labeled “P EPI” in FIG. 14). In other examples, the semiconductor layer 1404 may be omitted. The semiconductor device 1400 further includes a buried layer 1405 having an opposite second conductivity type (e.g., includes majority carrier dopants of a second type, such as n-type). In the illustrated example, the first conductivity type is p-type and the second conductivity type is n-type. In other implementations not explicitly shown, similar benefits and structures can be fabricated by reversing the conductivity types of various structures, for example, wherein the first conductivity type can be n-type and the second conductivity type can be p-type.

A semiconductor layer 1406 (e.g., epitaxial silicon, which may be referred to as a semiconductor layer 1406 or epitaxial layer 1406) extends over the substrate 1402 from the epitaxial layer 1404 (or from the semiconductor substrate 1402 if the epitaxial layer 1404 is omitted) and from the buried layer 1405. The semiconductor layer 1406 has the second conductivity type (e.g., includes n-type majority carriers) and includes a top surface that extends in a plane of the respective first and second directions X and Y. In one example, the semiconductor layer 1406 is or includes silicon, and the top surface of the semiconductor layer 1406 has a crystal orientation of Miller indices (100). In other examples, the semiconductor layer 1406 may have a crystal orientation different than Miller indices (100). An upper portion of the buried layer 1405 extends into a lower portion of the semiconductor layer 1406 in the illustrated example, for example, by diffusion of n-type dopants originally implanted in the epitaxial layer 1404 (or in the semiconductor substrate 1402 if the epitaxial layer 1404 is omitted) into the lower portion of the semiconductor layer 1406.

In the illustrated example, the transistor Q is an NPN transistor and includes a collector C implemented as an n-type collector region 1410 with a corresponding collector contact 1431 in the PMD layer 1433. The collector region 1410 extends downward along the third direction Z from the top surface of the semiconductor layer 1406 to the buried layer 1405 to form a collector of the transistor Q. The collector region 1410 has majority carriers of the second type with a dopant concentration that is greater than that of the n-type epitaxial layer 1406.

The semiconductor device 1400 has multiple elongated fin-shaped emitter regions 1416, each having majority carriers of the second conductivity type (n-type), and each of which extends with a high vertical aspect ratio (e.g., greater than 1) from the top surface of the semiconductor layer 1406 into a base region 1418. The individual emitter regions 1416 each have multiple faces with respective current emitting surfaces S1-S3 along respective junctions between the emitter regions 1416 and the base region 1418. The emitter regions 1416 are each laterally spaced apart from the collector region 1410 and can extend along an orthogonal direction into the page in the view of FIG. 14 to form a set of multiple fingers with current emitting faces along substantially vertical sidewalls S2 and S3 at an angle θ of approximately 90° to the plane of the top surface of the semiconductor layer 1406, as well as a current emitting face along a bottom side S1 of the respective emitter regions 1416. FIG. 14 schematically shows thick lines to depict current flow from the sidewalls S1, S2, and S3 of the emitter regions 1416 through respective junctions between the emitter regions 1416 and the base region 1418.

The base B of the transmitter Q in this example is formed by a base region 1418 with the first conductivity type (p-type), and the base B may include base sidewall guard regions 1417 along lateral sides of the base region 1418 and spaced apart from the emitter region 1416. In one example, the p-type dopant concentrations of the base sidewall guard regions 1417 is greater than the p-type dopant concentration of the base region 1418. In other implementations, the base sidewall guard regions 1417 can be omitted. The semiconductor device 1400 also includes a metallization structure 1430 with vertical metal interconnects 1431 and 1432 (e.g., vias or contacts including tungsten or other suitable conductive metal) in a pre-metal dielectric (PMD) layer 1433, and a metal trace features 1434 in a first interlevel or interlayer dielectric (ILD) layer 1435. The metallization structure 1430 in one example includes a third level with conductive metal terminals 1436, such as bond pads, die pads, etc., that can provide terminal connections to interconnect the semiconductor die 1401 and the transistor Q thereof, for example, by bond wire connections, or soldering of one or more terminals 1436 to a substrate or lead frame (not shown) during packaging of the semiconductor device 1400.

Described examples provide three-dimensional structures to facilitate enhanced area utilization for larger effective emitter-base area for enhanced current carrying capability without increasing overall size of a bipolar junction transistor. Because bipolar transistor current generation is proportional to emitter surface area, the described examples and other corresponding implementations facilitate increased current generation without increasing the die area traditionally required using a two dimensional emitter surface. KOH or other suitable etching techniques can be used to form triangular prism trenches and/or selective epitaxial growth can be used to create three-dimensional structures for forming bipolar transistor emitter structures without significantly increasing manufacturing cost or complexity to enable die shrinkage and/or enhanced transistor performance without sacrificing total current carrying capabilities. The described examples provide increased effective emitter area without increasing the transistor size with slight manufacturing process changes, such as additional photomask, cleaning steps, and nitride masking.

Modifications are possible in the described embodiments, and other embodiments are possible, within the scope of the claims.

1. A semiconductor device, comprising:
a base region having a first conductivity type, the base region extending into a top surface of a semiconductor layer;
a collector region having an opposite second conductivity type, the collector region extending from the top surface into the semiconductor layer and spaced apart from the base region; and
an emitter region having the second conductivity type, the emitter region extending from the top surface into the base region and having first and second faces along a junction between the emitter region and the base region.

2. The semiconductor device of claim 1, wherein the first and second faces of the emitter region are not parallel to one another and are not parallel to a plane of the top surface of the semiconductor layer.

3. The semiconductor device of claim 2, wherein the first and second faces of the emitter region are at respective nonzero first and second angles to a plane of the top surface of the semiconductor layer.

4. The semiconductor device of claim 1, further comprising a base sidewall guard region along a portion of the base region and spaced apart from the emitter region, and the base sidewall guard region having the first conductivity type, wherein a dopant concentration of the base sidewall guard region is greater than a dopant concentration of the base region.

5. The semiconductor device of claim 1, wherein:
the top surface of the semiconductor layer extends in a plane of orthogonal first and second directions; and
the emitter region includes an emitter finger that extends along the second direction.

6. The semiconductor device of claim 5, wherein:
the emitter finger is a first emitter finger;
the semiconductor device further comprises a second emitter finger of the emitter region adjacent to the first emitter finger, the second emitter finger extending along the second direction; and
the first and second emitter fingers are spaced apart from one another along the first direction.

7. The semiconductor device of claim 6, wherein the collector region includes a collector fin that extends along the second direction and is located laterally between the first and second emitter fingers.

8. The semiconductor device of claim 5, wherein the emitter finger includes a trench that extends into the top surface of the semiconductor layer, the trench having laterally opposite sidewalls that extend from the top surface of the semiconductor layer to a bottom of the trench.

9. The semiconductor device of claim 8, further comprising a metal layer filling the trench.

10. The semiconductor device of claim 8, further comprising a metal layer contacting the laterally opposite sidewalls and the bottom of the trench.

11. The semiconductor device of claim 8, wherein:
the semiconductor layer includes silicon; and
the top surface of the semiconductor layer has a crystal orientation of Miller indices (100).

12. The semiconductor device of claim 8, wherein the respective sidewalls of the trench extend to the bottom of the trench at an angle to the top surface of the semiconductor layer that is greater than 0 degrees and less than 90 degrees.

13. The semiconductor device of claim 8, wherein the bottom of the trench is approximately parallel to the top surface of the semiconductor layer.

14. A semiconductor device, comprising:
a base region having a first conductivity type, the base region extending into a top surface of a semiconductor layer, the top surface of the semiconductor layer extending in a plane of orthogonal first and second directions;
a collector region having an opposite second conductivity type, the collector region extending from the top surface into the semiconductor layer and spaced apart from the base region; and
an emitter region having multiple emitter fingers of the second conductivity type, the emitter fingers spaced apart from one another along the first direction and extending longitudinally along the second direction and into the semiconductor layer at an angle to the top surface of the semiconductor layer, each emitter finger having first and second faces with respective first and second current emitting surfaces along a junction between the emitter region and the base region.

15. A method, comprising:
forming a collector region in a semiconductor layer;
forming an angled structure in the semiconductor layer;
forming a base region in the angled structure of the semiconductor layer, the base region extending into a surface of the angled structure and spaced apart from the collector region, wherein the base region has a first conductivity type and the collector region has a second conductivity type opposite to the first conductivity type; and
forming an emitter region extending from the surface of the angled structure into the base region and having first and second faces along a junction between the emitter region and the base region, wherein the emitter region has the second conductivity type.

16. The method of claim 15, wherein forming the angled structure in the semiconductor layer includes etching a trench into a top surface of the semiconductor layer and spaced apart from the collector region.

17. The method of claim 16, wherein etching the trench includes performing an anisotropic etch process that forms the trench having laterally opposite sidewalls that extend from the top surface of the semiconductor layer to a trench bottom at an angle to the top surface of the semiconductor layer that is greater than 0 degrees and less than 90 degrees.

18. The method of claim 16, wherein etching the trench includes performing a crystallographic wet etch process that forms the trench having laterally opposite sidewalls that extend from the top surface of the semiconductor layer to a trench bottom at an angle to the top surface of the semiconductor layer that is greater than 0 degrees and less than 90 degrees.

19. The method of claim 18, wherein the semiconductor layer includes silicon, the top surface of the semiconductor layer having a crystal orientation of Miller indices (100).

20. The method of claim 18, wherein the trench bottom is approximately parallel to the top surface of the semiconductor layer.

21. The method of claim 16, further comprising forming a metal layer contacting sidewalls of the trench.
